(19) United States
(12) Patent Application Publication
(10) Pub. No.: US 2024/0387760 A1
(43) Pub. Date: Nov. 21, 2024

(54) HEAT DISSIPATING STRUCTURES FOR SOLAR CELL ARRAYS FOR USE IN SPACE APPLICATIONS

(71) Applicant: Daniel Derkacs, Albuquerque, NM (US)

(72) Inventor: Daniel Derkacs, Albuquerque, NM (US)

(73) Assignee: SOLAERO TECHNOLOGIES CORP., Albuquerque, NM (US)

(21) Appl. No.: 18/119,402

(22) Filed: May 15, 2023

(51) Int. Cl. H01L 31/052; H01L 31/18; H02S 20/30

(52) U.S. Cl. CPC H01L 31/052; H01L 31/184; H02S 20/30

(57) ABSTRACT

A supporting panel for use in connection with a multijunction solar cell array, and its method of fabrication, the being disposed solar cell array for transmitting IR light in the spectral range of a wavelength of 5 to 50 nm which represents unused an undesired heat energy, thereby providing thermodynamic radiative cooling of the solar cell array when deployed in space outside the earth's atmosphere.

### REFERENCE TO RELATED APPLICATIONS

This application is related to U.S. patent application Ser. No. 18/056,161 filed Nov. 16, 2022.

This application is also related to co-pending U.S. patent application Ser. No. 15/449,590 filed Mar. 3, 2017 now U.S. Pat. No. 10,479,053.

This application is also related to U.S. patent application Ser. No. 17/191,355 filed Mar. 3, 2021, now U.S. Pat. No. 11,329,181.

All of the above related applications are incorporated herein by reference in their entirety.

### BACKGROUND OF THE INVENTION

### Field of the Invention

The present disclosure relates to heat dissipating structures used in connection with single or multijunction solar cell arrays for space applications, and the fabrication of such structures, and more particularly the design and specification of radiative or heat dissipating elements on such structures.

### Description of the Related Art

Solar power from photovoltaic cells, also called solar cells, has been predominantly provided by silicon semiconductor technology. In the past several years, however, high-volume manufacturing of III-V compound semiconductor multijunction solar cells for space applications has accelerated the development of such technology not only for use in space but also for terrestrial solar power applications. Compared to silicon, III-V compound semiconductor multijunction devices have greater energy conversion efficiencies and generally more radiation resistance, although they tend to be more complex to properly specify and manufacture. Typical commercial III-V compound semiconductor multijunction solar cells have energy efficiencies that exceed 27% under one sun, air mass 0 (AM0) illumination, whereas even the most efficient silicon technologies generally reach only about 18% efficiency under comparable conditions. The higher conversion efficiency of III-V compound semiconductor solar cells compared to silicon solar cells is in part based on the ability to achieve spectral splitting of the incident radiation through the use of a plurality of photovoltaic regions with different band gap energies, and accumulating the current from each of the regions.

In satellite and other space related applications, the size, mass and cost of a satellite power system are dependent on the power and energy conversion efficiency of the solar cells used. Putting it another way, the size of the payload and the availability of on-board services are proportional to the amount of power provided. Thus, as payloads become more sophisticated, and applications anticipated for five, ten, twenty or more years, the power-to-weight ratio and lifetime efficiency of a solar cell becomes increasingly more important, and there is increasing interest not only the amount of power provided at initial deployment, but over the entire service life of the satellite system, or in terms of a design specification, the amount of power provided at the “end of life” (EOL).

Typical III-V compound semiconductor solar cells are fabricated on a semiconductor wafer in vertical, multijunction structures or stacked sequence of solar subcells, each subcell formed with appropriate semiconductor layers and including a p-n photoactive junction. Each subcell is designed to convert photons over different spectral or wavelength bands to electrical current. After the sunlight impinges on the front of the solar cell, and photons pass through the subcells, with each subcell being designed for photons in a specific wavelength band. After passing through a subcell, the photons that are not absorbed and converted to electrical energy propagate to the next subcells, where such photons are intended to be captured and converted to electrical energy.

The energy conversion efficiency of multijunction solar cells is affected by such factors as the number of subcells, the thickness of each subcell, the composition and doping of each active layer in a subcell, and the consequential band structure, electron energy levels, conduction, and absorption of each subcell, as well as the effect of its exposure to radiation in the ambient environment over time. The identification and specification of such design parameters is a non-trivial engineering undertaking, and would vary depending upon the specific space mission and customer design requirements. Since the power output is a function of both the voltage and the current produced by a subcell, a simplistic view may seek to maximize both parameters in a subcell by increasing a constituent element, or the doping level, to achieve that effect. However, in reality, changing a material parameter that increases the voltage may result in a decrease in current, and therefore a lower power output. Such material design parameters are interdependent and interact in complex and often unpredictable ways, and for that reason are not “result effective” variables that those skilled in the art confronted with complex design specifications and practical operational considerations can easily adjust to optimize performance. Electrical properties such as the short circuit current density (J_{sc}), the open circuit voltage (V_{oc}), and the fill factor (FF), which determine the efficiency and power output of the solar cell, are affected by the slightest change in such design variables, and as noted above, to further complicate the calculus, such variables and resulting properties also vary, in a non-uniform manner, overtime (i.e. during the operational life of the system).

The operational condition of solar cells is satellite and other apace operations are extreme and dictate design features for space solar cells that are not needed in terrestrial applications. For example, the temperature ranges and temperature cycles encountered in space vary from −175° C. to +180° C.

The band gap of a semiconductor decreases with temperature. For example, GaAs will have a band gap of 1.44 eV at 0° C. but 1.376 eV at 126° C. A drop in band gap will result in a drop in voltage in the subcell, and therefore a decrease in the power output of the solar cell. As a result, there is increase interest in providing means for keeping the solar cells as cool as possible by increasing the emissivity of the surroundings elements supporting or framing the solar cells.

A space solar cell often includes a cover glass over the semiconductor device to provide radiation resistant shielding from particles in the space environment which could damage the semiconductor material. The cover glass is typically a ceria doped borosilicate glass which is typically from three to six mils in thickness and attached by a transparent adhesive to the solar cell.

The assembly of individual solar cells together with electrical interconnects and the cover glass form a so-called “CIC” (Cell-Interconnected-Cover glass) assembly. Which are then typically electrically connected to form an array of series-connected solar cells. The solar cells used in many arrays often have a substantial size; for example, in the case of the single standard substantially “square” solar cell trimmed from 100 mm wafer with cropped corners, the solar cell can have a side length of seven cm or more.

In summary, it is evident that the differences in design, materials, and configurations between a space-qualified III-V compound semiconductor solar cell and assemblies and arrays of such solar cells, on the one hand, and silicon solar cells or other photovoltaic devices used in terrestrial applications, on the other hand, are so substantial that prior teachings associated with silicon or other terrestrial photovoltaic system are simply unsuitable and have no applicability to the design configuration of space-qualified solar cells and arrays. Indeed, the design and configuration of components adapted for terrestrial use with its modest temperature ranges and cycle times often teach away from the highly demanding design requirements for space-qualified solar cells and arrays and their associated components.

The present disclosure proposes design features for a solar cells array support or panel having a heat dissipating surface for increasing the efficiency of the solar cells in converting solar energy to electrical energy in a space environment.

### SUMMARY OF THE DISCLOSURE

### Objects of the Disclosure

It is an object of the present disclosure to provide increased photoconversion efficiency in a solar cell assembly for space applications by incorporating a structure on the exposed surface of the panel disposed under the single or multijunction solar cell array so as to increase the emissivity of the panel and more effectively radiate the heat absorbed or produced by the solar cell.

Is another object of the present disclosure to provide increased photoconversion efficiency in a solar cell for space applications by incorporating a retroreflector surface structure mounted on a panel supporting the solar cell array.

It is another object of the present disclosure to increase the thermodynamic radiative cooling of the solar cell when deployed in space outside the atmosphere through employing a surface structure on a supporting frame or panel mounting the solar cell array with improved emissivity.

It is another object of the present disclosure to increase the thermodynamic radiative cooling of the solar cell when deployed in space outside the atmosphere through employing a frame or panel that changes and minimizes the reststrahlen effect associated with the use of the frame or panel to improve emissivity.

Is another object of the present disclosure to provide a frame or panel having an array of geometrical structures on the surface structure thereof to enable the radiative cooling of the active element supported by the frame or panel.

Is another object of the present disclosure to provide support for a solar cell array having an array of geometrical structures on the surface structure thereof that minimizes the reststrahlen effect to enable the radiative cooling of the active elements disposed on or between the supports.

Is an object of the present disclosure to provide a single or multijunction solar cell array which the surface panel in which the cell heats the supporting panel via conduction which in turn emits the heat by means of a high emissivity surface and enables the emission of a greater amount of heat than the use of a panel without such a high emissivity surface.

Some implementations of the present disclosure may incorporate or implement fewer of the aspects and features noted in the foregoing objects.

### Features of the Disclosure

All ranges of numerical parameters set forth in this disclosure are to be understood to encompass any and all subranges or “intermediate generalizations” subsumed herein. For example, a stated range of 5 to 50 microns for a value should be considered to include any and all subranges beginning with a minimum value of 5 microns or more and ending with a maximum value of 50 microns les, e.g., 5 to 10 microns, or 10 to 30 microns, or 45 to 20 microns.

Briefly, and in general terms, the present disclosure provides a support for placement over the bottom surface of a solar cell array comprising a body and an array of geometrical structures disposed adjacent to one another on the exposed surface of the body, each geometrical structure including a base and apex and forming a plurality of vias between the geometrical structures, wherein the geometrical structures are sized and shaped to increase the transmissivity of infrared radiation in a wavelength range of 5 to 50 microns from the solar cell into the adjoining environment.

In some embodiments, the array of geometrical structures are sized and shaped so as to change the index of refraction and thereby increase the IR emissivity and corresponding IR transmissivity of the top surface of the body, and thereby reduce the retention of heat in the body caused by the radiative transfer of heat generated in the solar cell during its illumination and operation.

In some embodiments the geometric structure has a base, a width and a height, and wherein the ratio between the width of the base and the height of the geometric structure is in the range of 1:1 to 1:6.

In some embodiments a height of the geometrical structure is in the range of 5 to 300 microns.

In some embodiments a pitch of the array of the geometrical structures is in the range of 5 to 50 microns.

In some embodiments the base and the apex of the geometrical structure are connected by a single planar surface.

In some embodiments the base and the apex of the geometrical structure are connected by a first and a second surface, the first surface being adjacent to the base and the second surface being adjacent to the apex.

In some embodiments, at least one of the first and second surfaces are planar or flat.

In some embodiments the second surface is at least twice the area of the first surface.

In some embodiments the base and the apex are connected by two truncated cone shaped bodies.

In some embodiments the base is circular or polygonal in shape.

In some embodiments the apex of the geometrical structures is a substantially planar surface which is smaller than the base.

In some embodiments, the geometrical structures are surface perturbations on the body.

In some embodiments the body is a carbon fiber composite.

In some embodiments the thickness of the body is approximately 150 microns.

In some embodiments the body includes a first structural member disposed adjacent to the solar cell array, and a second layered member disposed adjacent to the bottom surface of the first structural member.

In some embodiments the second layer member includes a molded array of the above-described geometrical structures.

In some embodiments the geometrical structures are formed by wet or dry chemical etching of the body or of the second layered member.

In some embodiments the geometrical structures are formed by lithography.

In another aspect, the present disclosure provides a method comprising providing a solar cell array, providing a body disposed below the solar cell array and comprising a bottom surface; and laser etching the bottom surface of the body to form an array of geometrical structures disposed adjacent to another on the surface of the body, each geometrical structure including a base and an apex and forming a plurality of vias between the geometrical structures, wherein the geometrical structures are sized and shaped to increase emissivity (or equally reduce reflectivity) of infrared radiation from the solar cell array through the body in a wavelength range of 5 to 50 microns from the solar cell array into the adjoining environment store the surface of the body emits radiation to cold space.

In another aspect, the present disclosure provides a support for placement under the solar cell array comprising a body composed of a carbon fiber component disposed adjacent to the solar cell; and an array of geometrical structures disposed on the bottom surface of the body, each structure including a base and an apex and being disposed adjacent to one another and forming a plurality of vias on the top surface of the body that are sized and shaped so as to change the index of refraction and thereby increase the IR emissivity and corresponding reduce the IR reflectivity of the surface of the body, and thereby reduce the retention of heat in the body caused by the conductive transfer of heat generated in the solar cell during the illumination and operation of the solar cell.

In another aspect, the present disclosure provides a method of fabricating a support for bonding over the bottom surface of a single or multijunction solar cell array comprising providing a body; laser etching an array of geometrical structures have a base width between 5 to 50 microns and disposed on the bottom surface of the body, each structure including a base and an apex and being disposed adjacent to one another and forming a plurality of vias on the bottom surface of the body; and bonding the body to the bottom surface of the single or multijunction solar cell array.

In some embodiments, the solar cell is an III-V compound semiconductor multijunction solar cell.

In some implementations of the present disclosure may incorporate or implement fewer of the aspects and features noted in the foregoing summaries.

Additional aspects, advantages, and novel features of the present disclosure will become apparent to those skilled in the art from this disclosure, including the following detailed description as well as by practice of the disclosure. While the disclosure is described below with reference to preferred embodiments, it should be understood that the disclosure is not limited thereto. Those of ordinary skill in the art having access to the teachings herein will recognize additional applications, modifications and embodiments in other fields, which are within the scope of the disclosure as disclosed and claimed herein and with respect to which the disclosure could be of utility.

### BRIEF DESCRIPTION OF THE DRAWINGS

The disclosure will be better and more fully appreciated by reference to the following detailed description when considered in conjunction with the accompanying drawings, wherein:

FIG. 1 depicts a CIC including two solar cell mosaic portions according to the present disclosure;

FIGS. 2A, 2B and 2C are highly simplified cross-sectional views of the surface portion of a variety of different bodies with surface treatments or structures according to the present disclosure;

FIG. 3 is a graph that depicts the reflectivity of the surface of a body having the composition of these used in fabricating a support for a CIC;

FIG. 4A illustrates an array of cones in one embodiment of the geometrical structure implemented on the body according to the present disclosure;

FIG. 4B illustrates an array of pyramids on the surface of the body according to the present disclosure;

FIG. 5A is a graph depicting (i) the change in temperature of a body as a function of the hemispherical emissivity through the surface of the body, and (ii) the corresponding solar cell efficiency for a typical triple-junction solar cell mounted in a CIC with the body having the hemispherical emissivities shown on the x-axis and the corresponding temperature of the CIC assembly shown on the y-axis, and

FIG. 5B is a graph similar to that of FIG. 5A but calibrated with respect to temperature of a CIC in operation a GEO orbit.

### DESCRIPTION OF THE EMBODIMENTS

Details of the present invention will now be described including exemplary aspects and embodiments thereof. Referring to the drawings and the following description, like reference numbers are used to identify like or functionally similar elements, and are intended to illustrate major features of exemplary embodiments in highly simplified diagrammatic manner. Moreover, the drawings are not intended to depict every feature of the actual embodiment nor the relative dimensions of the depicted elements, and are not to scale.

Reference through this specification to “one embodiment” or “an embodiment” means that a particular feature, structure, or characteristic described in connection with the embodiment is included in at least one embodiment of the present invention. Thus, the appearance of the phrases “in one embodiment” or “in an embodiment” in various places throughout this specification are not necessarily all referring to the same embodiment. Furthermore, the particular features, structures, or characteristics may be combined in any manner in one or more embodiments.

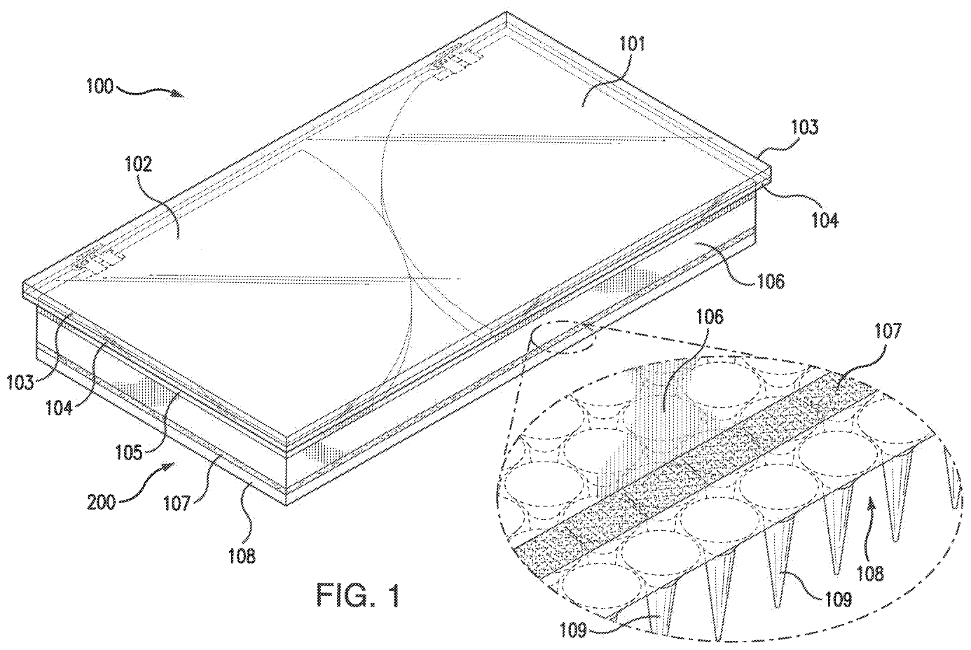

FIG. 1 depicts a CIC 100 including two solar cell mosaic portions 101/105 and 102/105 with an adhesive 104 on the surface thereof bonded to cover glass 103. In some embodiments a single solar cell may be arranged under the cover glass 103, and in other embodiments a plurality of solar cell mosaic portions may be positioned, aligned and arranged under the single cover glass 103. The CIC 100 is mounted on a support 200.

The support 200 includes a rigid or flexible structural support 106 which is attached under the bottom of the CIC 100 by an adhesive layer (not shown). In some embodiments the structural support may be a rigid aluminum honeycomb panel, or a flexible polyimide layer or roll.

In some embodiments, the structural support includes a carbon fiber composite film layer in which the geometrical structures are formed on the bottom surface of the film, either as a separate layer or different material, or as part of the film layer.

In some embodiments, the geometrical structures are implemented in a metallic layer on the bottom of the structural support.

In some embodiments, the geometrical structures are implemented on a polyimide film disposed on the bottom side of the structural support, wherein in some embodiments the polyimide film is composed of a poly (4,4′oxydiphenylene-pyromellitimide).

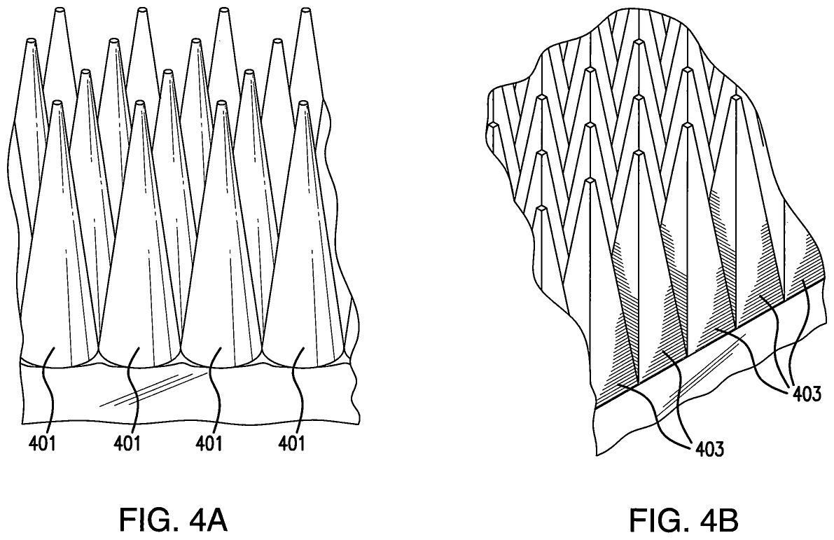

The call-out on the lower right-hand side of FIG. 1 depicts a highly enlarged bottom surface view of the support 200 illustrating an array of geometrical structures 109 according to the present disclosure. Although the embodiment specifically illustrated are conical geometrical structures, the geometrical structure 109 may alternatively be a pyramid with any polygonal base such as a square or hexagonal, or any other pillar type structure having a base and an apex, with the diameter of the structure decreasing from the base to the apex, either continuously or incrementally in one or more steps to a different slope. Examples of other embodiments of the geometrical structure 109 is shown in FIGS. 4A and 4B below. The present disclosure is not limited to the specific structure shown, but may be any structure that provides the change in refractive index and augmenting IR radiation and emissivity from the surface.

Although in the depicted embodiment all of the geometrical structures on the support 200 are identical in size and shape, in other embodiments the shape may be different, the size may be different, or both the size and the shape of the various structures within the array may differ.

In some embodiments, the width of the base of each structure 109 may be in the approximate range of 5 to 50 microns. That ratio of the width of the base to the height may range from 1:1 to 1:6, so correspondingly the height of each of the geometrical structures 109 may be in the range of 5 to 300 microns.

In one embodiment, the width of the base is approximately 20 microns, and the ratio of the width of the base to the height is 1:3. In other embodiments, the width of the base may be 10 microns, 15 microns, 25 microns, or 30 microns.

The apex of each of the geometrical structures may be a point or a small flat surface. The structure area of the flat surface may be 2%, 5%, or 7% of the area of the base, or any suitable value between 0% and 10%.

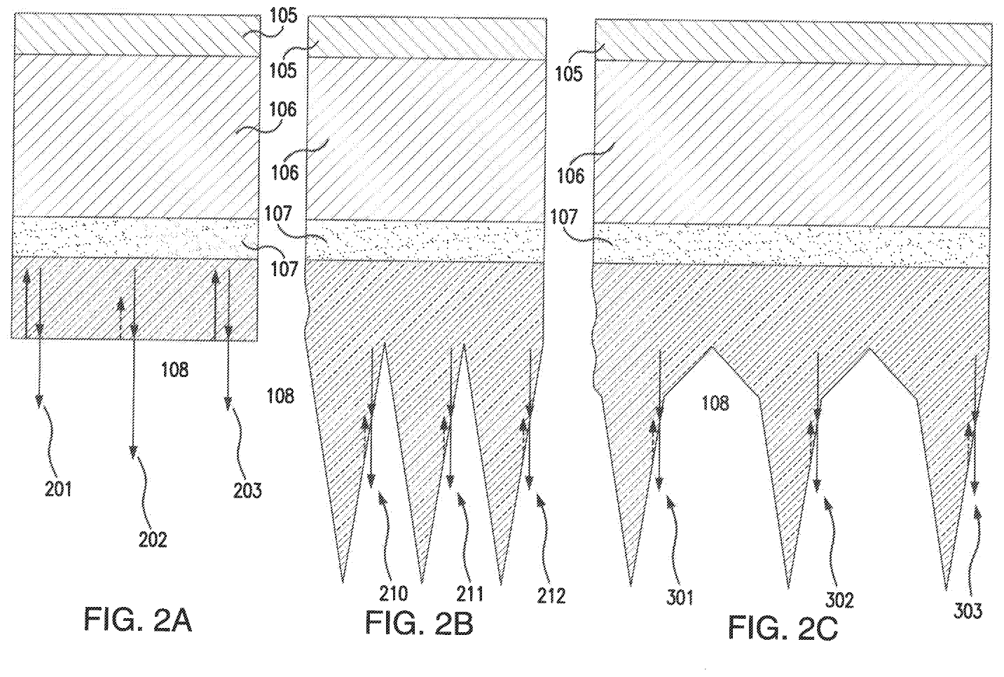

FIGS. 2A, B and 2C are highly simplified cross-sectional views of the surface portion of a variety of different bodies to illustrate the reflectivity (as well as the transmissivity) of the surface when IR radiation is emitted of different wavelengths arising from the interior temperature of the body. As we noted above, is a photovoltaic panel or solar cell array in space and illuminated by the incident sunlight, the individual solar cells produce heat as a byproduct of being less than 100% efficient in converting photons to electricity. The heat generated results in the solar cell typically attaining an operating temperature of between 50° and 70° C. when deployed in low earth orbit (LEO) of between 200 and 1000 km from the surface of the earth, and between 30° and 40° C. when deployed in geospatial space orbit (GEO) of approximately 36,000 km from the surface of the earth. The generated heat is conductively transferred to the bonded support mounted over the bottom surface of the solar cell, and the temperature of the body correspondingly rises and is radiatively transferred to the adjacent space environment, thereby cooling the solar cell.

An understanding of the black body IR radiation in a broad-spectrum range and the effect of surface features (or lack thereof) of the body is necessary at this point. FIG. 2A illustrates the reflectivity (as well as the transmissivity) of the surface of a body at three different IR spectral wavelengths.

The arrows associated with reference number 201 depict the transmission of certain IR radiation through the surface of the body, and the reflection of a portion of that IR radiation back into the body. The length of the arrows in this and subsequent FIGS. 2B and 2C represent the magnitude of the associated radiation in a highly simplified and diagrammatic manner. In the example depicted by the arrow in 201, the radiation wavelength is a first value, which represents relatively poor reflectivity/transmissivity. The numeric value of the wavelength being selected depends on the material and is intended to depict the transmission of radiation purely for illustrative purposes.

Reference number 202 depicts the radiative transfer and reflectivity associated with radiation with a second wavelength of different from the first wavelength. Compared with 201, it is evident that the reflectivity at the surface is much less than that of 201, and thus a greater amount of IR radiation, and therefore heat, is transmitted/emitted into space, thereby providing better cooling of the solar cell.

As noted above, the efficiency of a solar cell is directly related to its operating temperature. The lower the operating temperature, the greater the efficiency. Since as noted in the examples of 201, 202 and 203 IR radiation wavelength, the reflectivity of the material 108 empirically varies depending upon the incident wavelength of the radiation due to the inherent compositional features of the material that are typically used in space applications. Applicant's attention was therefore directed to examining the effect of surface features of the body which may change the reflectivity at specific identified wavelengths, therefore increase the amount of IR radiation associated with these wavelengths, and corresponding by reduce the operating temperature of the CIC by allowing greater radiative transfer of heat from the solar cell through the bottom of the support.

A variety of geometrical structures implemented on the surface of the body can affect the IR reflectivity at the surface, as illustrated with the highly simplified examples of FIGS. 2B and 2C which illustrate in FIG. 2B a simple cone and in FIG. 2C a two-step cone with planar surfaces at different angles or slopes with respect the base.

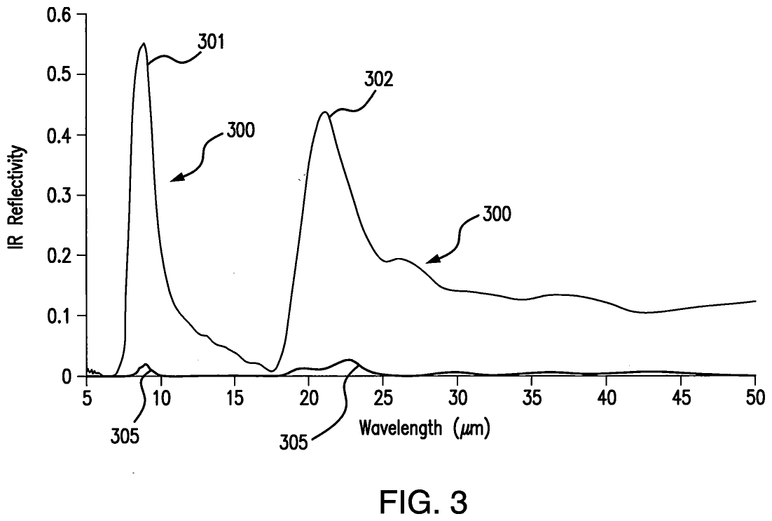

An examination of the length of the arrows depicted in FIGS. 2B and 2C illustrates the effect of the reflectivity (and corresponding transmissivity through the surface) that is relatively uniform over the wavelength spectrum under consideration. Numerically, rather than an IR reflectivity of 30%, 40%, 50% or more, depending upon wavelength, the IR reflectivity though the surface of the body may be reduced to nearly 0%, as will be subsequently illustrated in FIG. 3.

One of the characteristics features of the geometric structures according to the present disclosure is that the dimensions of the various structures, including the pitch between individual structural elements, or the depth of the vias separating the structural elements, is numerically approximately that of the wavelength value of IR radiation at issue.

FIG. 3 is a graph that depicts the reflectivity of the surface of a body having the composition of these used in fabricating a support for a CIC used for space applications over a broad wavelength spectrum from 5 to 50 microns typical of IR radiation emitted to the external environment. The first curve 300 represents the IR reflectivity of a flat body as currently commercially used for supporting CICs in space applications. The peaks 301 and 302 of high IR reflectivity of over 40% centered around a hypothetical first wavelength of and a second wavelength are notable. The specific wavelengths depicted are arbitrary for the purpose of illustration, since the reflectivity/transmissivity as a function of wavelength would depend on the material. The second curve 305 represents the IR reflectivity of a body having the same composition but having an array of geometrical structures according to the present disclosure implemented on the surface of the body. The substantially lower IR reflectivity through the entire broad wavelength range is notable.

FIG. 4A illustrates an array of cones 401 at the geometrical structure implemented on the surface of the body and FIG. 4B an array of pyramids 403 on the surface according to the present disclosure.

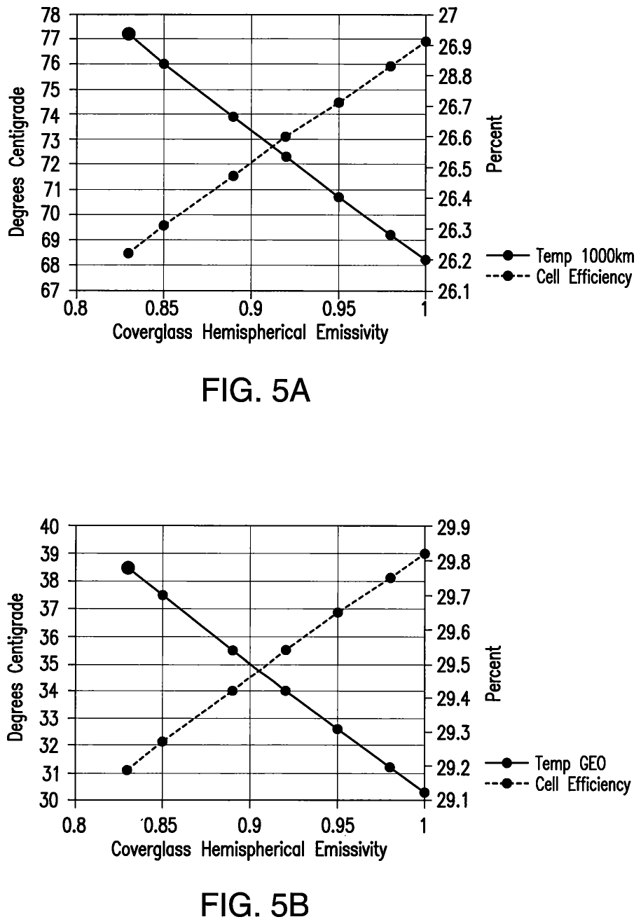

FIG. 5A is a graph depicting (i) the change in temperature of a body as a function of the hemispherical emissivity through the surface of the body, and (ii) the corresponding solar cell efficiency for a typical triple-junction solar cell mounted in a CIC with the supporting body having the hemispherical emissivities shown on the x-axis and the corresponding temperature of the CIC assembly shown on the y-axis. It is noted that being able to lower the temperature from 77° C. to 68° C. (associated with a 1000 km LEO orbit) results in an improvement in efficiency from 26.2% to 26.9%.

FIG. 5B is a graph similar to that of FIG. 5A but calibrated with respect to temperature of CIC in GEO orbit, depicted on the y-axis from 30 to 39° C. The corresponding ability of the body according to the present disclosure to lower the temperature from 39° C. to 31° C. results in an improvement in efficiency from 29.2% to 29.8%.

It will be understood that each of the elements described above, or two or more together, also may find a useful application in other types of structures or constructions differing from the types of structures or constructions described above.

The terminology used in this disclosure is for the purpose of describing specific identified embodiments only and is not intended to be limiting of different examples or embodiments.

In the drawings, the position, relative distance, lengths, widths, and thicknesses of supports, substrates, layers, regions, films, etc., may be exaggerated for presentation simplicity or clarity. Like reference numerals designate like elements throughout the specification. It will be understood that when an element such as an element layer, film, region, or feature is referred to as being “on” another element, it can be disposed directly on the other element or the presence of intervening elements may also be possible. In contrast, when an element is referred to as being disposed “directly on” another element, there are no intervening elements present.

Furthermore, those skilled in the art will recognize that boundaries and spacings between the above described units/operations are merely illustrative. The multiple units/operations may be combined into a single unit/operation, a single unit/operation may be distributed in additional units/operations, and units/operations may be operated at least partially overlapping in time. Moreover, alterative embodiments may include multiple instances of a particular unit/operation, and the order of operations may be altered in various other embodiments.

The terms “substantially”, “essentially”, “approximately”, “about”, or any other similar expression relating to particular parametric numerical value are defined as being close to that value as understood by one of ordinary skill in the art in the context of that parameter, and in one non-limiting embodiment the term is defined to be within 10% of that value, in another embodiment within 5% of that value, in another embodiment within 1% of that value, and in another embodiment within 0.5% of that value.

The term “coupled” as used herein is defined as connected, although not necessarily directly or physically adjoining, and not necessarily structurally or mechanically. A device or structure that is “configured” in a certain way is arranged or configured in at least that described way, but may also be arranged or configured in ways that are not described or depicted.

The terms “front”, “back”, “side”, “top”, “bottom”, “over”, “on”, “above”, “beneath”, “below”, “under”, and the like in the description and the claims, if any, are used for descriptive purposes and not necessarily for describing permanent relative positions. It is understood that the terms so used are interchangeable under appropriate circumstances such that the embodiments of the disclosure described herein are, for example, capable of operation in other orientations than those illustrated or otherwise described herein. For example, if the assembly in the figures is inverted or turned over, elements of the assembly described as “below” or “beneath” other elements or features would then be oriented “above” the other elements or features. Thus, the exemplary term “below” can encompass both an orientation of above and below. The assembly may be otherwise oriented (rotated by a number of degrees through an axis).

The terms “front side” and “backside” refer to the final arrangement of the panel, integrated cell structure or of the individual solar cells with respect to the illumination or incoming light incidence.

In the claims, the word ‘comprising’ or ‘having’ does not exclude the presence of other elements or steps than those listed in a claim. It is understood that the terms “comprises”, “comprising”, “includes”, and “including” if used herein, specify the presence of stated components, elements, features, steps, or operations, components, but do not preclude the presence or addition of one or more other components, elements, features, steps, or operations, or combinations and permutations thereof.

The terms “a” or“an”, as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to disclosures containing only one such element, even when the claim includes the introductory phrases “one or more” or “at least one” and indefinite articles such as “a” or “an”. The same holds true for the use of definite articles.

The present disclosure can be embodied in various ways. To the extent a sequence of steps are described, the above described orders of the steps for the methods are only intended to be illustrative, and the steps of the methods of the present disclosure are not limited to the above specifically described orders unless otherwise specifically stated. Note that the embodiments of the present disclosure can be freely combined with each other without departing from the spirit and scope of the disclosure.

Although some specific embodiments of the present disclosure have been demonstrated in detail with examples, it should be understood by a person skilled in the art that the above examples are only intended to be illustrative but not to limit the scope and spirit of the present disclosure. The above embodiments can be modified without departing from the scope and spirit of the present disclosure which are to be defined by the attached claims. Accordingly, other implementations are within the scope of the claims.

Thus, while the description of the semiconductor device described in the present disclosure has focused primarily on solar cells or photovoltaic devices, persons skilled in the art know that other optoelectronic devices, such as thermophotovoltaic (TPV) cells, photodetectors and light-emitting diodes (LEDS), are very similar in structure, physics, and materials to photovoltaic devices with some minor variations in doping and the minority carrier lifetime. For example, photodetectors can be the same materials and structures as the photovoltaic devices described above, but perhaps more lightly-doped for sensitivity rather than power production. On the other hand, LEDs can also be made with similar structures and materials, but perhaps more heavily-doped to shorten recombination time, thus radiative lifetime to produce light instead of power. Therefore, this invention also applies to photodetectors and LEDs with structures, compositions of matter, articles of manufacture, and improvements as described above for photovoltaic cells.

Without further analysis, from the forgoing others can, by applying current knowledge, readily adapt the present invention for various applications. Such adaptions should and are intended to be comprehended within the meaning and range of equivalence of the following claims.

1. A supporting panel for a solar cell assembly for use in a satellite or space vehicle comprising:
a structural support having a top side and a bottom side;
a CIC assembly including a solar cell mounted on the top side of the structural support; and
the bottom side of the structural support includes an array of geometrical structures, each geometrical structure having a base and an apex and being disposed adjacent to one another and sized and shaped to radiate IR light in the wavelength range of 5 to 50 microns thereby increasing the IR emissivity through the bottom side of the structural support and thereby reduce the retention of heat in the supporting panel caused by the conduction of heat generated in the CIC assembly during the illumination and operation of the solar cell in the CIC assembly.

2. A supporting panel as defined in claim 1, wherein the base is polygonal in shape and has a width in range of 5 to 50 microns.

3. A supporting panel as defined in claim 1, wherein the distance between the base and the apex is in range of 5 to 300 microns.

4. A supporting panel as defined in claim 1, wherein the apex is a point or a small area forming the top of each of the geometrical structures.

5. A supporting panel as defined in claim 1, wherein the base of each geometric structure is circular in shape, and the geometrical structure is a cone.

6. A supporting panel as defined in claim 1, wherein the base and the apex are connected by a single planar surface.

7. A supporting panel as defined in claim 1, wherein the CIC assembly is flat and rectangular and approximately 4 mils in thickness, and includes a cover glass that is cerium doped.

8. A supporting panel as defined in claim 1, wherein the base and the apex are connected by a first and a second surface, the first surface being adjacent to the base, the second being adjacent to the apex.

9. A supporting panel as defined in claim 8, wherein the second surface is at least twice the area of the first surface.

10. A supporting panel as defined in claim 1, wherein the base and the apex are connected by two truncated cone shaped bodies.

11. A supporting panel as defined in claim 1, wherein the ratio between the width of the base and the height of the geometric structure is in the range of 1:1 to 1:6.

12. A supporting panel as defined in claim 1, wherein the ratio between the width of the base and the height of the geometric structure is 1:3.

13. A supporting panel as defined in claim 1, wherein the base is a square or a hexagon in shape with a width of approximately 20 microns.

14. A supporting panel as defined in claim 7, wherein upon receiving light through the cover glass of the CIC, the operation of solar cell generates heat in the solar cell which is transferred to the adjacent cover glass body and the adjacent structural support by conduction.

15. A supporting panel as defined in claim 1, wherein the increase in IR emission results in an operating temperature decrease in excess of 5° C. to 7° C., and thereby an increase in absolute solar cell efficiency of at least 0.5%.

16. A supporting panel as defined in claim 1, wherein the structural support is an aluminum honeycomb structure.

17. A supporting panel as defined in claim 1, wherein the structural support includes a carbon fiber composite file in which the geometrical structures are on the bottom surface of the film.

18. A supporting panel as defined in claim 1, wherein the geometrical structures are implemented in a metallic layer on the bottom of the structural support.

19. A supporting panel as defined in claim 1, wherein the geometrical structures are implemented on a polyimide film disposed on the bottom side of the structural support.

20. A method of fabricating support for bonding over the bottom surface or a single or multijunction solar cell array comprising:
providing a body;
laser etching an array of geometrical structures have a base width between 5 to 50 microns and disposed on the bottom surface of the body, each structure including a base and an apex and being disposed adjacent to one another and forming a plurality of vias on the bottom surface of the body; and
bonding the body to the bottom surface of the single or multijunction solar cell array.
